(19) United States
(12) Patent Application Publication
(10) Pub. No.: US 2024/0267038 A1
(43) Pub. Date: Aug. 8, 2024

(54) POWER SWITCH ASSEMBLY WITH CO-PACKAGED PROTECTION FUNCTION

(71) Applicant: Infineon Technologies Austria AG, Villach (AT)

(72) Inventors: Wolfgang FRANK, Augsburg (DE); Richard KNIPPER, Regensburg (DE); Andreas KALT, Krumpendorf am Wörthersee (AT); Simone FABBRO, Udine (IT); Davide GIACOMINI, Valdengo (IT)

(21) Appl. No.: 18/433,808

(22) Filed: Feb. 6, 2024

(30) Foreign Application Priority Data
Feb. 7, 2023 (EP) 23155462

(51) Int. Cl. H03K 17/08

(52) U.S. Cl. CPC H03K 17/08

(57) ABSTRACT

A power switch assembly includes a power switch, a driving circuit configured to control the power switch, a protection device associated with a first current duration and a first current value and arranged between the driving circuit and the power switch, the protection device being configured to decouple the driving circuit from the power switch based on the first current duration and the first current value, and a clamping device associated with a second current duration and a second current value and arranged between the driving circuit, the protection device and the power switch, the clamping device being configured to couple the power switch to a second assembly load terminal of the power switch assembly based on the second current duration and the second current value. The first current duration is longer than the second current duration. The first current value is lower than the second current value.

### CROSS-REFERENCE TO RELATED APPLICATION

This application claims priority to European Patent Application No. 23155462 filed on Feb. 7, 2023, the content of which is incorporated by reference herein in its entirety.

### TECHNICAL FIELD

The implementation generally relates to protecting driving circuits against short circuits at a power switch and more precisely to the integration of such protection inside a power switch assembly.

### BACKGROUND

During operation of a power switch, failure situations may occur during which a current may flow between a first load terminal of the power switch and a control terminal of the power switch. Such a current may lead to a high voltage at an output of a driving circuit coupled to the control terminal. The high voltage may then cause overheating and potentially destruction or even decapsulation of the driving circuit. The risk posed by the high current may be particularly pronounced for driving circuits with high internal resistances, such as gate drivers having a high internal resistance or solid-state isolators.

In discrete systems, e.g., systems in which the power switch and the driving circuit are placed on a printed circuit board (PCB) and coupled to one another via traces on the PCB, various elements may be placed between the driving circuit and the power switch to protect the driving circuit against these currents. However, if the power switch and the driving circuit are arranged as a power switch assembly, e.g., if the power switch and the driving circuit are arranged in a single package, discrete protection solutions are not available.

Therefore, it is an objective of the present disclosure to protect driving circuits against currents caused by short circuits between terminals of a power switch in power switch assemblies.

### SUMMARY

To achieve this objective, the present disclosure provides a power switch assembly having an assembly control terminal, a first assembly load terminal and a second assembly load terminal, including a power switch having a control terminal, a first load terminal and a second load terminal, a driving circuit coupled to the control terminal and configured to control the power switch responsive to a control signal applied to the assembly control terminal, a protection device having a first current duration and a first current value and arranged between the driving circuit and the control terminal, the protection device being configured to decouple the driving circuit from the control terminal based on the first current duration and the first current value, a clamping device having a second current duration and a second current value and arranged between the driving circuit, the protection device and the second load terminal, the clamping device being configured to couple the control terminal to the second load terminal based on the second current duration and the second current value, wherein the first current duration is longer than the second current duration, and wherein the first current value is lower than the second current value.

The present disclosure further provides a protection method for a power switch assembly including a driving circuit, a protection device, a clamping device, a power switch having a control terminal, a first load terminal and a second load terminal, wherein the driving circuit is coupled to the control terminal via the protection device and the clamping device is arranged between the driving circuit, the protection device and the second load terminal, including operating the power switch based on a control signal provided to the driving circuit, while operating the power switch, decoupling the driving circuit from the control terminal based on a first current value and a first current duration of the protection device and, while operating the power switch, coupling the control terminal to the second load terminal based on a second current value and a second current duration of the clamping device, wherein the first current duration is longer than the second current duration, and wherein the first current value is lower than the second current value.

### BRIEF DESCRIPTION OF THE DRAWINGS

Examples of the present disclosure will be described with reference to the following appended drawings, in which like reference signs refer to like elements.

FIG. 1 illustrates a power switch assembly according to examples of the present disclosure.

FIGS. 2A and 2B illustrate example driving circuits of the power switch assembly of FIG. 1 according to examples of the present disclosure.

FIG. 3 illustrates example clamping devices of the power switch assembly of FIG. 1 according to examples of the present disclosure.

FIGS. 4A and 4B illustrate example protection devices of the power switch assembly of FIG. 1 according to examples of the present disclosure.

FIG. 5 shows an example current and associated events, which may trigger or not trigger the protection device of the power switch assembly of FIG. 1 according to examples of the present disclosure.

FIG. 6 provides a flowchart of a protection method for a power switch assembly according to examples of the present disclosure.

It should be understood that the above-identified drawings are in no way meant to limit the present disclosure. Rather, these drawings are provided to assist in understanding the present disclosure. The person skilled in the art will readily understand that aspects of the present implementation shown in one drawing may be combined with aspects in another drawing or may be omitted without departing from the scope of the present disclosure.

### DETAILED DESCRIPTION

The present disclosure generally provides a power switch assembly and corresponding protection method. The power switch assembly includes a power switch and a driving circuit coupled to a control terminal of the power switch. To protect the driving circuit against various short circuit events at the power switch, the power switch assembly further includes a protection device and a clamping device. The clamping device is configured to clamp, e.g., to couple, the control terminal to a second load terminal of the power switch. The protection device is configured to decouple the driving circuit from the control terminal. While both the clamping device and the protection device perform their respective protection functions based on a current present at the control terminal, they perform their respective functions only if different current values are exceeded for different current durations. This ensures that different current events at the control terminal trigger different protection responses based on the energy associated with the different current events.

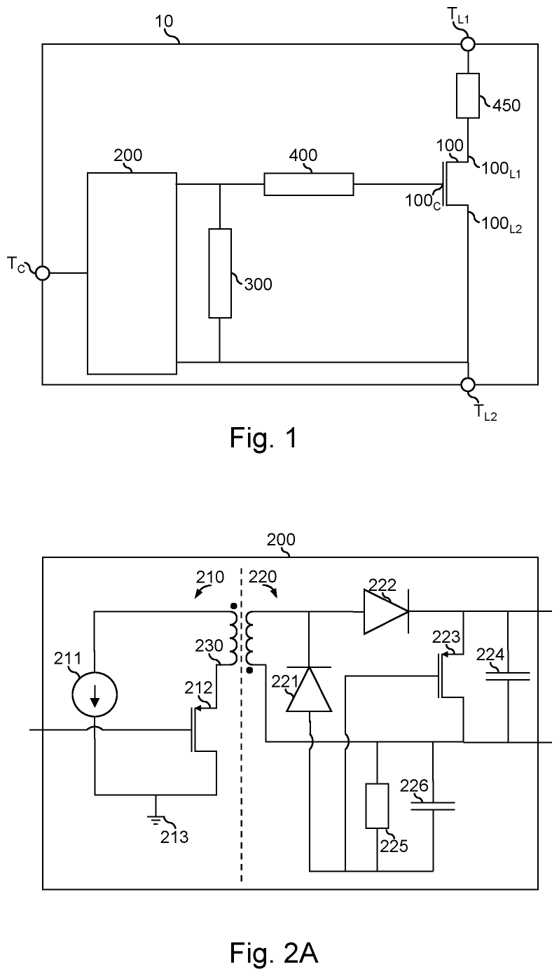

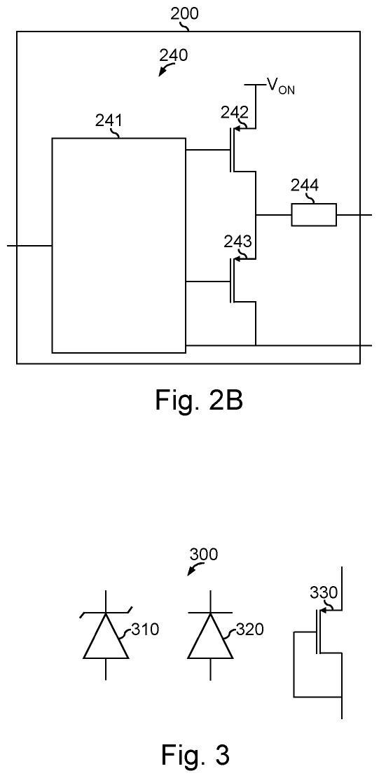

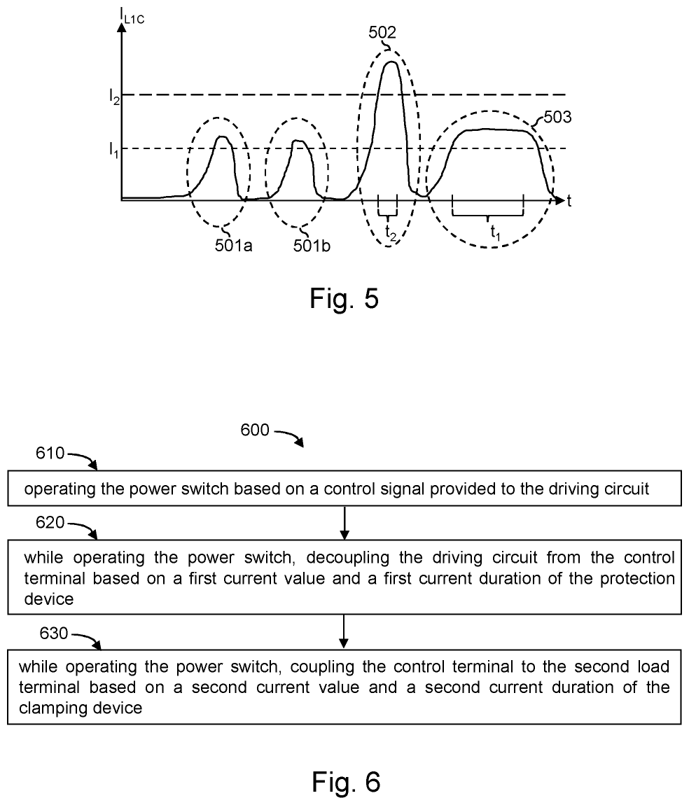

This general concept will be explained with reference to the appended drawings, with FIG. 1 providing an overview of the power switch assembly and FIGS. 2A to 4B illustrating various example aspects of the power switch assembly. In addition, FIG. 5 provides an illustration of the triggering of the respective protection functions. Finally, FIG. 6 illustrates the corresponding protection method.

FIG. 1 illustrates a power switch assembly 10. Power switch assembly 10 has an assembly control terminal T_{C}, a first assembly load terminal T_{L1} and a second assembly load terminal T_{L2}.

Assembly control terminal T_{C} may be configured to be coupled to an output of a control circuit, such as a microcontroller, and may accordingly be configured to receive a control signal indicating whether power switch assembly 10 should be switched into a conducting state or a non-conducting state. The control signal may for example be a pulse width modulation (PWM) signal, e.g., power switch assembly 10 may for example be controlled based on a duration of on-pulses of the control signal. The control signal may be an on-off keying (OOK) signal, e.g., power switch assembly 10 may for example be controlled based on the presence and the absence of a logic high value of the control signal. It will be understood that PWM signals and OOK signals are merely provided as an example control signal. Power switch assembly 10 may be controlled based on any type of control signal suitable for controlling power switches.

First assembly load terminal T_{L1} may be configured to be coupled to a positive supply voltage DC+, which may for example provide a supply voltage of 450V, 600V, 1200V or 1800V. It will be understood that these voltage levels are merely provided as examples of a high voltage supply and may have any other voltage level depending on the application for which power switch assembly 10 is to be used. First assembly load terminal T_{L1} may further be configured to be coupled to another power switch assembly 10, for example if two power switch assemblies 10 are used in a half-bridge configuration, or more generally to any type of power switch.

Second assembly load terminal T_{L2} may be configured to be coupled to a negative supply voltage DC−, which may for example be 0V. It will be understood that the negative supply voltage DC− may also be at a voltage level above 0V or below 0V, depending on the application for which power switch assembly 10 is to be used. More generally, negative supply voltage DC− may be at any voltage level below the voltage level of positive supply voltage DC+. Second assembly load terminal T_{L2} may further be configured to be coupled to another power switch assembly 10, for example if two power switch assemblies 10 are used in half-bridge configuration, or more generally to any type of power switch.

Assembly control terminal T_{C}, first assembly load terminal T_{L1} and second assembly load terminal T_{L2} may be part of, for example comprised in, a package of power switch assembly 10. The package may for example be formed using material typically used to form packages of integrated circuits, such as plastic materials like epoxy or ceramics. The package may consequently enclose all components of power switch assembly 10, which will be discussed in the following. Power switch assembly 10 includes a power switch 100, a driving circuit 200, a clamping device 300 and a protection device 400. Power switch assembly 10 may further include a load path protection device 450. The power switch 100, the driving circuit 200, the clamping device 300, the protection device 400, and the load path protection device 450 of power switch assembly 10 may be integrated on a single substrate that is encapsulated in the package. Thus, power switch assembly 10 may be an integrated circuit (IC) with each component of power switch assembly 10 being integrated on a single substrate that is encapsulated by the package. That is to say, power switch assembly 10 may be an IC with each of its components being co-packaged on the single substrate within the package. The single substrate may be a single multi-layered substrate. Assembly control terminal T_{C}, first assembly load terminal T_{L1}, and second assembly load terminal T_{L2} may provide electrical connections between power switch assembly 10 and external components that are external to the package.

Power switch 100 has a control terminal 100_{C}, a first load terminal 100_{L1} and a second load terminal 100_{L2}. Control terminal 100_{C} is coupled to driving circuit 200 via protection device 400. First load terminal 100_{L1} is coupled to first assembly load terminal T_{L1}, either directly or via load path protection device 450. Second load terminal 100_{L2} is coupled to second assembly load terminal T_{L2}. Accordingly, the expression “coupled” refers to both direct connections, as in the case of second load terminal 100_{L2}, and connections with intervening elements, as in the case of control terminal 100_{C} and first load terminal 100_{L1}.

Power switch 100 may be any kind of power switch configured to have a high voltage blocking capability. For example, power switch 100 may be able to block voltages above at least 400V, such as 450V, 900V, 1200V or 1800V. To achieve such voltage blocking capabilities, power switch 10 may for example be a silicon or silicon carbide (SiC) metal oxide field effect transistor (MOSFET), a silicon or SiC insulated gate bipolar transistor (IGBT) or a Gallium nitride high electron mobility transistor (GaN-HEMT). It will be understood that both the voltage levels and the technology types discussed with regard to power switch 10 are merely provided as an example. The present disclosure may be practiced with other high voltage levels and other power switch technologies than those mentioned here.

Driving circuit 200 is coupled to control terminal 100_{C} and configured to control power switch 100 responsive to the control signal applied to the assembly control terminal T_{C} discussed above. In other words, driving circuit 200 is configured to switch power switch 100 on and off based on the control signal received by power switch assembly 100. To this end, driving circuit 200 may for example be implemented as shown in FIGS. 2A and 2B.

As shown in FIG. 2A, driving circuit 200 may be a solid-state isolator, which may be configured to generate one of a turn-on voltage and a turn-off voltage based on the control signal applied to the assembly control terminal.

Driving circuit 200 of FIG. 2A includes a galvanic isolation barrier 230, which in the example of FIG. 2A is shown as a transformer and may thus also be referred to as transformer 230. Transformer 230 divides driving circuit 200 into an input side 210, e.g., the circuitry coupled to the primary side of transformer 230, and an output side 220, e.g., the circuitry coupled to the secondary side of transformer 230. Transformer 230 may be formed based on any type of galvanic isolation, such as a coreless transformer.

Input side 210 may include an input voltage source 211, an input switch 212 and an input ground 213. A control terminal of input switch 212 may be coupled to assembly control terminal T_{C} and may thus receive the control signal, which may for example be an OOK signal. While input switch 212 is controlled based on the control signal to be in a conductive state, a magnetization current may flow through the primary winding of transformer 230. The magnetization current flowing through the primary side of transformer 230 may cause magnetic energy to be stored in transformer 230 and may thereby cause a voltage drop at the secondary side of transformer 230. The voltage drop at the primary side may be inverted with respect to the voltage drop at the primary side of transformer 230 caused by input voltage source 211. Once input switch 212 is controlled based on the control signal to no longer be in the conductive state, the magnetic energy stored in transformer 230 may be discharged at the secondary side of transformer 230.

Output side 220 may include a first diode 221, a second diode 222, a turn-off switch 223, a turn-on capacitor 224, resistor 225 and a turn-off capacitor 226. First diode 221, resistor 225 and a turn-off capacitor 226 may also collectively be referred to as a negative charge pump. The two output terminals of output side 220 may respectively be coupled to control terminal 100_{C} and second assembly load terminal T_{L2}.

While input switch 212 is controlled to cause transformer 230 to provide the inverse voltage drop at the secondary side, turn-off capacitor 226 may be charged. The energy charged in turn-off capacitor 226 may be used to charge a control terminal of turn-off switch 223, causing turn-off switch 223 to be conductive. While turn-off switch 223 is caused to be conductive, control terminal 100_{C} and second assembly load terminal T_{L2} may be coupled, keeping power switch 100 in a non-conductive state. Further, since the inverse voltage at the secondary side of transformer 230 causes a potential at the anode of second diode 222 to be below the potential at the cathode of second diode 222, second diode 222 blocks current from flowing toward control terminal 100_{C}.

Once input switch 212 is controlled to no longer be in the conductive state, the voltage at the secondary side of transformer 230 is no longer inverted. Accordingly, second diode 222 may no longer block current from flowing toward control terminal 100_{C}. This may allow the energy stored in transformer 230 to be discharged towards control terminal 100_{C}, causing energy to be stored in turn-on capacitor 224. The energy stored in turn-on capacitor 224 may in turn charge control terminal 100_{C}, causing power switch 100 to be in a conductive state. In addition, turn-off capacitor 226 may be discharged during the discharging of the energy stored in transformer 230, causing the control terminal of turn-off switch 223 to likewise be discharged and thereby causing turn-off switch 223 to be non-conductive. Accordingly, turn-off switch 223 may no longer couple control terminal 100_{C} to second assembly load terminal T_{L2}, thereby enabling charging control terminal 100_{C}.

As can be seen from the discussion of FIG. 2A, driving circuit 200 in the example of FIG. 2 is coupled to control terminal 100_{C} via the output side 230, which may have an internal resistance of several kΩ, for example 100 kΩ. Accordingly, driving circuit 200 of FIG. 2A may be considered as having a high internal resistance.

As shown in FIG. 2B, driving circuit 200 may be a gate driver, which may be configured to selectively couple the control terminal to one of a turn-on voltage source and a turn-off voltage source.

Driving circuit 200 of FIG. 2B may be gate driver 240, which may include a control logic 241, a turn-on transistor 242, a turn-off transistor 243 and an internal on-resistance 244. It will be understood that gate driver 240 may include further components, in particular an isolation region, for example if power switch assembly 10 is to be used as a high-side switch in a half-bridge configuration. Such an isolation region may for example be arranged between control logic 241 and turn-on transistor 242 as well as turn-off transistor 243.

Control logic 241 may be any kind of control logic, such as a microcontroller, which is configured to receive the control signal and control power switch 100 accordingly. To this end, control logic 241 may be configured to be coupled to assembly control terminal T_{C} in order to receive the control signal, which may for example be a PWM signal. If the control signal indicates that power switch assembly 10 should be switched into the conductive state, control logic 241 may cause turn-on transistor 242 to be conductive, thereby coupling turn-on voltage VON to control terminal 100_{C} via internal on-resistance 244. Analogously, if the control signal indicates that power switch assembly 10 should be switched into the non-conductive state, control logic 241 may cause turn-off transistor 243 to be conductive, thereby coupling control terminal 100_{C} to second assembly load terminal T_{L2} and second load terminal 100_{L2}.

The internal on-resistance 244 may in some examples have a value of several kΩ, for example 100 kΩ. Accordingly, gate driver 240 may be considered as having a high internal resistance. It will be understood that internal on-resistance 244 is merely shown as an individual component in FIG. 2B in order to illustrate the fact that gate driver 240 may have a high internal resistance. In example implementations of gate driver 240, the high internal resistance may be provided by turn-on transistor 242 and turn-off transistor 243. In other words, internal on-resistance 244 may not be present as an individual component.

While driving circuit 200 of both FIGS. 2A and 2B is described as having a high internal resistance, it will be understood that the present disclosure is not limited to such driving circuits and may also be practiced with driving circuits having low internal resistances.

Protection device 400 is arranged between driving circuit 200 and control terminal 100_{C} and has a first current duration and a first current value. For example, protection device 400 may be associated with the first current duration and the first current value for providing a protection function. Protection device 400 may react to energy corresponding to a current flowing through protection device 400 and perform the protection function based on the current. Based on the first current duration and the first current value, protection device 400 is configured to decouple driving circuit 200 from control terminal 100_{C}. In other words, protection device 400 is configured to decouple driving circuit 200 from control terminal 100_{C} based on a first energy absorbed by or dissipated in protection device 400 corresponding to the current flowing through protection device 400.

Generally speaking, electric energy absorbed by a device, e.g., for example stored, may be expressed as

$$E = U * Q \qquad ( 1 )$$

with E denoting energy, U denoting a voltage across the device and Q denoting a charge absorbed by the device in equation (1). Charge Q absorbed by the device may be expressed as

$$Q = I * t \qquad ( 2 )$$

with I denoting the current flowing through the device and t denoting the duration for which the current flows through the device. Substituting charge Q in equation (1) with equation (2) leads to the following modified equation for the absorbed energy:

$$E = U * I * t \qquad ( 3 )$$

Finally, substituting voltage U based on Ohm's law modifies equation (3) as follows:

$$E = R * {I}^{2} * t \qquad ( 4 )$$

In equation (4), R denotes an internal resistance of the device. Accordingly, the first energy based on which protection device 400 is configured to decouple driving circuit 200 from control terminal 100_{C} may be expressed based on equation (4) as follows:

$${E}_{1} = R * {{I}_{1}}^{2} * {t}_{1} \qquad ( 5 )$$

In equation (5), E₁ denotes the first energy absorbed by protection device 400, R denotes an internal resistance of protection device 400, I₁ denotes the first current value and t₁ denotes the first current duration. The internal resistance of protection device 400 depends on the implementation of protection device 400 and the technology used to implement protection device 400. The first current value and the first current level define the type of fault condition against which protection device 400 is configured to protect by decoupling driving circuit 200 from control terminal 100_{C}. Accordingly, the fault condition is determined by how long a current indicative of the fault condition and at what current level the current indicative of the fault condition is to flow.

The current may be a current flowing between first load terminal 100_{L1} and control terminal 100_{C}. In other words, the current may be a current flowing if an isolation barrier between control terminal 100_{C} and first load terminal 100_{L1} fails. This current may lead to a high voltage at the output of the driving circuit if protection device 400 is not present, in particular if driving circuit 200 is implemented with a high internal resistance, such as internal on-resistance 244. In other words, by decoupling driving circuit 200 from control terminal 100_{C} based on the first current value and the first current duration, protection device 400 is configured to protect driving circuit 200 from a short circuit between control terminal 100_{C} and first load terminal 100_{L1} and to prevent a propagation of the high current along the signal path of the control signal.

Clamping device 300 is arranged between driving circuit 200, protection device 400 and second load terminal 100_{L2}. Clamping device 300 has a second current duration and a second current value. For example, clamping device 300 may be associated with the second current duration and the second current value for providing a clamping function. Clamping device 300 may react to energy corresponding to the current flowing through protection device 400 and perform the clamping function based on the current. Based on the second current duration and the second current value, clamping device 300 is configured to couple control terminal 100_{C} to second load terminal 100_{L2}. In other words, clamping device 300 may be configured to couple control terminal 100_{C} to second load terminal 100_{L2} based on clamping device 300 absorbing a second energy corresponding to the current flowing through protection device 400. Analogously to the first energy, the second energy may be expressed as follows:

$${E}_{2} = R * {{I}_{2}}^{2} * {t}_{2} \qquad ( 6 )$$

In equation (6), E₂ denotes the second energy absorbed by clamping device 300, R denotes an internal resistance of clamping device 300, I₂ denotes the second current value and t₂ denotes the second current duration. The internal resistance of the clamping device depends on the implementation of clamping device 300 and the technology used to implement clamping device 300. The second current value and the second current level define the type of fault condition against which clamping device 300 is configured to protect by coupling control terminal 100_{C} to second load terminal 100_{L2}.

As discussed above with regard to protection device 400, the fault condition in the case of protection device 300 is likewise determined by how long a current indicative of the fault condition and at what current level the current indicative of the fault condition is to flow. In the case of protection device 300, the fault condition may for example be an electrostatic discharge (ESD) event. More generally, the fault conditions against which protection device 400 and clamping device 300 protect differ. Accordingly, the first current duration is longer than the second current duration and the first current value is lower than the second current value. In other words, protection device 400 is configured to protect against short circuits characterized by a comparatively lower current occurring over longer periods of time while clamping device 300 is configured to protect against short circuits characterized by a comparatively higher current occurring over shorter periods of time.

In some examples of the present disclosure, the first current duration may be in the range of milliseconds while the second current duration may in the range of microseconds. Thus, the first current duration and the second current duration may be in ranges of different orders of magnitude. Correspondingly, the first current value may be a value up to 100 mA while the second current value may at least be 500 mA. It will be understood that these numeric examples are merely provided as an example to help in understanding the difference between the first current duration and the second current duration as well as between the first current value and the second current value.

Examples of short circuit or triggering events not triggering or triggering, respectively, the protection of one of clamping device 300 and protection device 400 is shown in FIG. 5. FIG. 5 illustrates a current I_{L1C} flowing from first load terminal 100_{L1} to control terminal 100_{C} and through protection device 400 and clamping device 300 over time. Current I_{L1C} includes two non-triggering events 501a and 501b as well as two triggering events 502 and 503.

Non-triggering events 501a and 501b exceed first current value I₁ but not for the first current duration t₁. Further, non-triggering events 501a and 501b exceed second current duration t₂ but do not exceed second current value I₂.

Triggering event 502 exceeds both second current value I₂ and second current duration t₂, thus triggering protection device 300. Triggering event 503 exceeds both first current value I₁ and first current duration t₁, thus triggering protection device 400. In other words, protection device 400 may be configured to decouple driving circuit 200 from control terminal 100_{C} if the current flowing through protection device 400 exceeds first current value I₁ for the entire first current duration t₁. Likewise, clamping device 300 may be configured to couple control terminal 100_{C} to second load terminal 100_{L2} if the current flowing through protection device 300 exceeds second current value I₂ for the entire second current duration t₂.

It will be understood that the timeline in FIG. 5 is provided merely as an example. During operation of power switch assembly 10, many non-triggering events may occur, with long operating durations therebetween without any non-triggering events. Likewise, depending on the implementation of clamping device 300 and protection device 400, at least events triggering clamping device 300 may occur more than once at various times during operation of power switch assembly 10.

In summary, protection device 400 is configured to be triggered once protection device 400 has absorbed the first energy while clamping device 300 is configured to be triggered once clamping device has absorbed the second energy. The first energy is characterized by the first current value and the first current value while the second energy is characterized by the second current value and the second current value. Given that the first current value is lower than the second current value and that the first current duration is longer than the second current duration, clamping device 300 and protection device 400 are configured to protect against different types of short circuits. Clamping device 300 is configured to protect against short circuits characterized by a high current for a short time while protection device 400 is configured to protect against short circuits characterized by a lower current for a longer time.

It will be understood that clamping device 300 and protection device 400 are not triggered if the first energy and the second energy are respectively absorbed by clamping device 300 and protection device 400 outside the time frame specified by the first current duration and the second duration. Evidently, given that power switch assembly 10 may be configured to operate for thousands of operating hours, clamping device 300 and protection device 400, both devices may absorb energies exceeding the first energy and the second energy. However, since such energies may be absorbed over many operating hours rather than during the comparatively short timeframes defined by the first current duration and the second current duration, such absorbed energies do not trigger clamping device 300 and protection device 400.

To prevent clamping device 300 from being triggered based on the first energy, clamping device 300 may be configured to keep control terminal 100_{C} and second load terminal 100_{L2} decoupled if the current flowing through protection device 400 exceeds the first current value for the entire first current duration. This ensures that clamping device 300 is only triggered in the case of a short circuit against which clamping device 300 is configured to protect against and not in the case of a short circuit against which protection device 400 is configured to protect.

Given that clamping device 300 and protection device 400 are configured to protect against different types of short circuits with different associated energies, their protection mechanism may also be not permanent and permanent, respectively. That is, protection device 400 may be configured to irreversibly decouple driving circuit 200 from control terminal 100_{C} (e.g., if the current flowing through protection device 400 exceeds the first current value I₁ for an entirety of the first current duration t₁), while clamping device 300 may be configured to reversibly couple control terminal 100_{C} to second load terminal 100_{L2} (e.g., if a the current flowing through protection device 400 exceeds the second current value I₂ for an entirety of the entire second current duration t₂). In other words, protection device 400 may at least partially disintegrate a section of the connection between driving circuit 200 and control terminal 100_{C}, while clamping device 300 may decouple control terminal 100_{C} from second load terminal 100_{L2} once the second energy has dissipated.

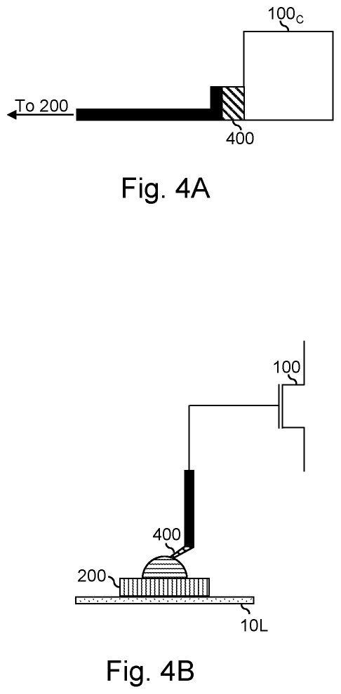

Based on the above discussed general concept of clamping device 300 and protection device 400, example implementations of clamping device 300 and protection device 400 in accordance with this general concept will be discussed in the following with reference to FIGS. 3 to 4B.

FIG. 3 illustrates three example implementations of clamping device 300, e.g., a Zener diode 310, a pn-junction 320 and a grounded n-metal oxide semiconductor (nMOS) transistor 330.

In the example of clamping device 300 being implemented by Zener diode 310, a cathode of Zener diode 310 is coupled to second load terminal 100_{L2}. Based on this orientation of Zener diode 310, clamping device 300 may be configured to controllably couple control terminal 100_{C} to second load terminal 100_{L2} based on a Zener voltage of Zener diode 310. In other words, Zener diode 310 may be configured to have a Zener voltage which is present if the second current value is exceeded for the second current duration.

In the example of clamping device 300 being implemented by pn-junction 320, a cathode of pn-junction 320 is coupled to second load terminal 100_{L2}. Based on this orientation of pn-junction 320, clamping device 300 may be configured to couple control terminal 100_{C} to second load terminal 100_{L2} based on a breakdown voltage pn-junction 320. In other words, pn-junction 320 may be configured to have a breakdown voltage which is present if the second current value is exceeded for the second current duration.

In the example of clamping device 300 being implemented by n-MOS transistor 330, a gate of n-MOS transistor 330 is coupled to second load terminal 100_{L2}. Based on this arrangement of n-MOS transistor 330, clamping device 300 may be configured to controllably couple control terminal 100_{C} to second load terminal 100_{L2} based on the voltage at second load terminal 100_{L2}.

FIGS. 4A and 4B illustrate two example implementations of protection device 400.

FIG. 4A shows a simplified top view of an implementation of power switch assembly 10, in which power switch 100, driving circuit 200, protection device 400 and clamping device 300 may be formed on a single multi-layered substrate (not shown in FIG. 4A). In the example implementation of FIG. 4A, protection device 400 may be formed on a metal layer of the multi-layered substrate as a connection between driving circuit 200 and control terminal 100_{C}. As illustrated in FIG. 4A, control terminal 100_{C} may be a control pad. Protection device 400 may be arranged between control pad 100_{C} and a metal trace continuing toward driving circuit 200, as indicated by the arrow in FIG. 4A. It will be understood that protection device 400 may also be arranged between two metal traces, one coming from control pad 100_{C} and the other one continuing toward driving circuit 200. Based on this arrangement, protection device 400 may provide a connection between control pad 100_{C} and the metal trace. In order to provide the protection function of protection device 400 discussed above, this connection may be configured to disintegrate based on the first current duration and the first current value. In other words, the connection may be configured to disintegrate if it has absorbed the first energy in the timeframe defined by the first current duration.

FIG. 4B shows a simplified side view of a section of power switch assembly 10. The simplified side view shows a lead frame 10L, on which driving circuit 200 is arranged. On top of driving circuit 200, dome-shaped conductive material is placed, which may for example be solder. The dome shaped conductive material may be coupled to a connection, such as a bond wire or a metal clip, which continues onward to control terminal 100_{C} of power switch 100. Protection device 400 may be integrated into the connection to provide a disintegration location. The disintegration location may be configured to disintegrate based on the first current duration and the first current value in order to decouple driving circuit 200 and control terminal 100_{C}. To this end, protection device 400 may be made of a material which disintegrates if it absorbs the second energy during the timeframe defined by the first current duration.

Load path protection device 450 may be configured to decouple first assembly load terminal T_{L1} from first load terminal 100_{L1} based on the first current duration and the first current value. That is, load path protection device 450 may provide the same protection function as protection device 400 based on the same energy. In other words, load path protection device 450 may provide, if present in power switch assembly 10, an additional protection in the load path in addition to the protection provided by protection device 400 in the control path against a high current flowing into power switch assembly 10 via first assembly load terminal T_{L1}. Load path protection device 450 may thus be implemented similarly to protection device 400. For example, load path protection device 450 may be configured to decouple first assembly load terminal T_{L1} from first load terminal 100_{L1} if a current flowing through the load path protection device 450 exceeds the first current value I₁ for the entirety of first current duration t₁.

FIG. 6 provides a flowchart of a protection method 600, which may protect power switch assembly 10 based on the principles discussed above. It will be understood that the order of the steps of method 600 shown in FIG. 6 is merely provided as an example. The steps may be performed in any order, may be performed concurrently, or one step may be performed a plurality of times without necessarily also performing the other step, depending on the respective implementation of method 600.

In step 610, method 600 operates power switch 100 based on the control signal provided to driving circuit 200.

In step 620, method 600 decouples driving circuit 200 from control terminal 100_{C} using protection device 400 based on the first current value and the first current duration of protection device 400 while operating power switch 100.

In step 630, method 600 couples control terminal 100_{C} to second load terminal 100_{L2} based on the second current value and the second current duration using clamping device 300 while operating power switch 100.

### Aspects

The implementation may further be illustrated by the following aspects.
Aspect 1: A power switch assembly having an assembly control terminal, a first assembly load terminal and a second assembly load terminal, comprising: a single substrate; a power switch having a control terminal, a first load terminal, and a second load terminal; a driving circuit coupled to the control terminal and configured to control the power switch responsive to a control signal applied to the assembly control terminal; a protection device associated with a first current duration and a first current value and arranged between the driving circuit and the control terminal, the protection device has a first terminal coupled to the driving circuit and a second terminal coupled to the control terminal, and the protection device being configured to decouple the driving circuit from the control terminal based on the first current duration and the first current value; and a clamping device associated with a second current duration and a second current value, the clamping device being coupled to the first terminal of the protection circuit, between the driving circuit and the protection device, and to the second load terminal, the clamping device being configured to couple the control terminal to the second load terminal based on the second current duration and the second current value, wherein the first current duration is longer than the second current duration, wherein the first current value is lower than the second current value, and wherein the power switch, driving circuit, the protection device, and the clamping device are integrated on the single substrate.
Aspect 2: The power switch assembly of Aspect 1, wherein: the protection device is configured to decouple the driving circuit from the control terminal if a current flowing through the protection device exceeds the first current value for an entirety of the first current duration, and the clamping device is configured to couple the control terminal to the second load terminal if the current flowing through the protection device exceeds the second current value for an entirety of the second current duration.
Aspect 3: The power switch assembly of Aspect 2, wherein the clamping device is configured to keep the control terminal and the second load terminal decoupled if the current flowing through the protection device exceeds the first current value for the entirety of the first current duration.
Aspect 4: The power switch assembly of Aspect 2, wherein the current is a current flowing between the first load terminal and the control terminal.
Aspect 5: The power switch assembly of any of Aspects 1-4, wherein: the protection device is configured to irreversibly decouple the driving circuit from the control terminal if the current flowing through the protection device exceeds the first current value for the entirety of the first current duration, and the clamping device is configured to reversibly couple the control terminal to the second load terminal if the current flowing through the protection device exceeds the second current value for the entirety of the second current duration.
Aspect 6: The power switch assembly of any of Aspects 1-5, wherein: the single substrate is a multi-layered substrate, and the power switch, the driving circuit, the protection device and the clamping device are formed on the single multi-layered substrate; and the protection device is formed on a metal layer of the multi-layered substrate as a connection between the driving circuit and the control terminal, wherein the connection is configured to disintegrate based on a current flowing through the protection device exceeding the first current value for an entirety of the first current duration.
Aspect 7: The power switch assembly of any of Aspects 1-6, wherein the protection device is integrated into a connection between the driving circuit and the control terminal to provide a disintegration location, the connection at the disintegration location being configured to disintegrate based on a current flowing through the protection device exceeding the first current value for an entirety of the first current duration.
Aspect 8: The power switch assembly of any of Aspects 1-7, further comprising: a load path protection device, the load path protection device being configured to decouple the first assembly load terminal from the first load terminal based on a current flowing through the load path protection device exceeding the first current value for an entirety of first current duration.
Aspect 9: The power switch assembly of any of Aspects 1-8, wherein the clamping device is configured to protect the driving circuit against an electrostatic discharge (ESD) event.
Aspect 10: The power switch assembly of any of Aspects 1-9, wherein the clamping device is one of: an n-metal oxide semiconductor (n-MOS) transistor, wherein a gate of the n-MOS transistor is coupled to the second load terminal, a Zener diode, wherein a cathode of the Zener diode is coupled to the second load terminal, or a pn-junction, wherein a cathode of the pn-junction is coupled to the second load terminal.
Aspect 11: The power switch assembly of any of Aspects 1-10, wherein the driving circuit is a solid-state isolator, the solid-state isolator being configured to generate one of a turn-on voltage and a turn-off voltage based on the control signal applied to the assembly control terminal.
Aspect 12: The power switch assembly of any of Aspects 1-11, wherein the driving circuit is a gate driver, the gate driver being configured to selectively couple the control terminal to one of a turn-on voltage source and a turn-off voltage source.
Aspect 13: The power switch assembly of Aspect 11, wherein the solid-state isolator includes a transformer comprising a primary side coupled to an input side of the driving circuit, and a secondary side coupled to an output side of the driving circuit.
Aspect 14: The power switch assembly of Aspect 13, wherein the output side of the driving circuit comprises a turn-off switch and negative charge pump configured to control the turn-off switch, and wherein the turn-off switch is configured, while in a conductive state, to couple the control terminal to the second assembly load terminal to maintain the power switch in a non-conductive state.
Aspect 15: The power switch assembly of Aspect 1, wherein the first current duration is within a first range of a first order of magnitude, and wherein the second current duration is within a second range of a second order of magnitude.
Aspect 16: The power switch assembly of Aspect 1, wherein the first current value is equal to or less than 100 mA, and wherein the second current value is equal to or greater than 500 mA.
Aspect 17: A protection method for a power switch assembly comprising a driving circuit, a protection device, a clamping device, and a power switch having a control terminal, a first load terminal, and a second load terminal, wherein the driving circuit is coupled to the control terminal via the protection device, and wherein the clamping device is coupled to a terminal of the protection circuit, arranged between the driving circuit and the protection device, and to the second load terminal, comprising: operating the power switch based on a control signal provided to the driving circuit; while operating the power switch, decoupling, by the protection device, the driving circuit from the control terminal based on a current flowing through the protection device exceeding a first current value for an entirety of a first current duration; and while operating the power switch, coupling, by the clamping device, the control terminal to the second load terminal based on the current flowing through the protection device exceeding a second current value for an entirety of a second current duration, wherein the first current duration is longer than the second current duration, and wherein the first current value is lower than the second current value.
Aspect 18: The protection method of any of Aspect 17, wherein the power switch, driving circuit, the protection device, and the clamping device are integrated on a single substrate.
Aspect 19: The protection method of any of Aspects 17-18, wherein the first current duration is within a first range of a first order of magnitude, and wherein the second current duration is within a second range of a second order of magnitude.
Aspect 20: The protection method of any of Aspects 17-19, wherein the first current value is equal to or less than 100 mA, and wherein the second current value is equal to or greater than 500 mA.
Aspect 21: A system configured to perform one or more operations recited in one or more of Aspects 1-20.
Aspect 22: An apparatus comprising means for performing one or more operations recited in one or more of Aspects 1-20.

The preceding description has been provided to illustrate a power switch assembly with a co-packaged protection function. It should be understood that the description is in no way meant to limit the scope of the present disclosure to the precise implementations discussed throughout the description. Rather, the person skilled in the art will be aware that the aspects of the present disclosure may be combined, modified or condensed without departing from the scope of the present disclosure as defined by the following claims.

1. A power switch assembly having an assembly control terminal, a first assembly load terminal and a second assembly load terminal, comprising:
a single substrate;
a power switch having a control terminal, a first load terminal, and a second load terminal;
a driving circuit coupled to the control terminal and configured to control the power switch responsive to a control signal applied to the assembly control terminal;
a protection device associated with a first current duration and a first current value and arranged between the driving circuit and the control terminal, the protection device has a first terminal coupled to the driving circuit and a second terminal coupled to the control terminal, and the protection device being configured to decouple the driving circuit from the control terminal based on the first current duration and the first current value; and
a clamping device associated with a second current duration and a second current value, the clamping device being coupled to the first terminal of the protection circuit, between the driving circuit and the protection device, and to the second load terminal, the clamping device being configured to couple the control terminal to the second load terminal based on the second current duration and the second current value,
wherein the first current duration is longer than the second current duration,
wherein the first current value is lower than the second current value, and wherein the power switch, driving circuit, the protection device, and the clamping device are integrated on the single substrate.

2. The power switch assembly of claim 1, wherein:
the protection device is configured to decouple the driving circuit from the control terminal if a current flowing through the protection device exceeds the first current value for an entirety of the first current duration, and
the clamping device is configured to couple the control terminal to the second load terminal if the current flowing through the protection device exceeds the second current value for an entirety of the second current duration.

3. The power switch assembly of claim 2, wherein the clamping device is configured to keep the control terminal and the second load terminal decoupled if the current flowing through the protection device exceeds the first current value for the entirety of the first current duration.

4. The power switch assembly of claim 2, wherein the current is a current flowing between the first load terminal and the control terminal.

5. The power switch assembly of claim 1, wherein:
the protection device is configured to irreversibly decouple the driving circuit from the control terminal if the current flowing through the protection device exceeds the first current value for the entirety of the first current duration, and
the clamping device is configured to reversibly couple the control terminal to the second load terminal if the current flowing through the protection device exceeds the second current value for the entirety of the second current duration.

6. The power switch assembly of claim 1, wherein:
the single substrate is a multi-layered substrate, and the power switch, the driving circuit, the protection device and the clamping device are formed on the single multi-layered substrate; and
the protection device is formed on a metal layer of the multi-layered substrate as a connection between the driving circuit and the control terminal, wherein the connection is configured to disintegrate based on a current flowing through the protection device exceeding the first current value for an entirety of the first current duration.

7. The power switch assembly of claim 1, wherein the protection device is integrated into a connection between the driving circuit and the control terminal to provide a disintegration location, the connection at the disintegration location being configured to disintegrate based on a current flowing through the protection device exceeding the first current value for an entirety of the first current duration.

8. The power switch assembly of claim 1, further comprising:
a load path protection device, the load path protection device being configured to decouple the first assembly load terminal from the first load terminal based on a current flowing through the load path protection device exceeding the first current value for an entirety of first current duration.

9. The power switch assembly of claim 1, wherein the clamping device is configured to protect the driving circuit against an electrostatic discharge (ESD) event.

10. The power switch assembly of claim 1, wherein the clamping device is one of:
an n-metal oxide semiconductor (n-MOS) transistor, wherein a gate of the n-MOS transistor is coupled to the second load terminal,
a Zener diode, wherein a cathode of the Zener diode is coupled to the second load terminal, or
a pn-junction, wherein a cathode of the pn-junction is coupled to the second load terminal.

11. The power switch assembly of claim 1, wherein the driving circuit is a solid-state isolator, the solid-state isolator being configured to generate one of a turn-on voltage and a turn-off voltage based on the control signal applied to the assembly control terminal.

12. The power switch assembly of claim 1, wherein the driving circuit is a gate driver, the gate driver being configured to selectively couple the control terminal to one of a turn-on voltage source and a turn-off voltage source.

13. A protection method for a power switch assembly comprising a driving circuit, a protection device, a clamping device, and a power switch having a control terminal, a first load terminal, and a second load terminal, wherein the driving circuit is coupled to the control terminal via the protection device, and wherein the clamping device is coupled to a terminal of the protection circuit, arranged between the driving circuit and the protection device, and to the second load terminal, comprising:
operating the power switch based on a control signal provided to the driving circuit;
while operating the power switch, decoupling, by the protection device, the driving circuit from the control terminal based on a current flowing through the protection device exceeding a first current value for an entirety of a first current duration; and
while operating the power switch, coupling, by the clamping device, the control terminal to the second load terminal based on the current flowing through the protection device exceeding a second current value for an entirety of a second current duration,
wherein the first current duration is longer than the second current duration, and
wherein the first current value is lower than the second current value.

14. The power switch assembly of claim 11, wherein the solid-state isolator includes a transformer comprising a primary side coupled to an input side of the driving circuit, and a secondary side coupled to an output side of the driving circuit.

15. The power switch assembly of claim 14, wherein the output side of the driving circuit comprises a turn-off switch and negative charge pump configured to control the turn-off switch, and
wherein the turn-off switch is configured, while in a conductive state, to couple the control terminal to the second assembly load terminal to maintain the power switch in a non-conductive state.

16. The power switch assembly of claim 1, wherein the first current duration is within a first range of a first order of magnitude, and
wherein the second current duration is within a second range of a second order of magnitude.

17. The power switch assembly of claim 1, wherein the first current value is equal to or less than 100 mA, and
wherein the second current value is equal to or greater than 500 mA.

18. The protection method of claim 13, wherein the power switch, driving circuit, the protection device, and the clamping device are integrated on a single substrate.

19. The protection method of claim 13, wherein the first current duration is within a first range of a first order of magnitude, and
wherein the second current duration is within a second range of a second order of magnitude.

20. The protection method of claim 13, wherein the first current value is equal to or less than 100 mA, and
wherein the second current value is equal to or greater than 500 mA.
